(19) United States
(12) Patent Application Publication
(10) Pub. No.: US 2015/0349136 A1
(43) Pub. Date: Dec. 3, 2015

(54) SEMICONDUCTOR DEVICE AND METHOD FOR MANUFACTURING THE SAME

(71) Applicant: Electronics and Telecommunications Research Institute, Daejeon (KR)

(72) Inventors: Jae Bon KOO, Daejeon (KR); Chan Woo PARK, Daejeon (KR); Soon-Won JUNG, Daejeon (KR); Bock Soon NA, Daejeon (KR); Sang Chul LIM, Daejeon (KR); Sang Seok LEE, Sejong (KR); Kyoung Ik CHO, Daejeon (KR); Hye Yong CHU, Daejeon (KR)

(21) Appl. No.: 14/611,142

(22) Filed: Jan. 30, 2015

(30) Foreign Application Priority Data
May 30, 2014 (KR) 10-2014-0065799

(51) Int. Cl. H01L 29/786; H01L 21/428; H01L 21/02; H01L 29/66

(52) U.S. Cl. CPC H01L 29/78603; H01L 29/66969; H01L 21/428; H01L 29/78606; H01L 29/7869; H01L 21/02288

(57) ABSTRACT

Methods for manufacturing semiconductor devices according to embodiments of the present invention may include providing a sacrificial substrate including a wiring region and a device region, sequentially forming a sacrificial layer and a buffer layer on the sacrificial substrate, forming a thin-film transistor on the buffer layer of the device region, forming a device protection element surrounding the thin-film transistor within the device region, forming a flexible substrate on the buffer layer, and exposing a surface of the buffer layer by separating the sacrificial substrate by removing the sacrificial layer. Since typical semiconductor process technologies may be directly used, the process compatibility may be improved, and semiconductor devices having high resolution and high performance may be manufactured. Furthermore, since the thin-film transistor is protected by the device protection element, the deformation of semiconductor devices under flexibility conditions may be prevented, thereby improving the reliability of the semiconductor devices.

### CROSS-REFERENCE TO RELATED APPLICATIONS

This U.S. non-provisional patent application claims priority under 35 U.S.C. §119 of Korean Patent Application No. 10-2014-0065799, filed on May 30, 2014, the entire contents of which are hereby incorporated by reference.

### BACKGROUND OF THE INVENTION

The present invention disclosed herein relates to a semiconductor device and a method for manufacturing the same, and more particularly, to a flexible semiconductor device and a method for manufacturing the same.

Flexible electronic circuits are able to maintain the functions and reliability thereof even though substrates of the flexible electronic circuits are bent or stretched. Such flexible electronic circuits may be applied to various fields of, e.g., sensor skins for robots, wearable communication devices, implantable bio-devices and next-generation displays. Accordingly, various researches have been conducted to implement such flexible electronic devices.

A method for manufacturing a semiconductor device using a flexible substrate may be classified into two types. According to a first-type method, a semiconductor device is formed on a silicon substrate or a glass substrate which allows a high-temperature process, and then transferred to a flexible substrate. According to a second-type method, a semiconductor device is directly formed on a flexible substrate.

### SUMMARY OF THE INVENTION

The present invention provides a flexible semiconductor device having high performance, high resolution and high reliability and a method for manufacturing the same.

Embodiments of the present invention provide methods for manufacturing a semiconductor device, the methods comprising: providing a sacrificial substrate including a wiring region and a device region, sequentially forming a sacrificial layer and a buffer layer on the sacrificial substrate, forming a thin-film transistor on the buffer layer of the device region, forming a device protection element surrounding the thin-film transistor within the device region, forming a flexible substrate on the buffer layer on which the device protection element is formed, and exposing a surface of the buffer layer by separating the sacrificial substrate by removing the sacrificial layer.

In other embodiments of the present invention, semiconductor devices comprise: a flexible substrate including a device region and a wiring region, a thin-film transistor embedded within the flexible substrate of the device region, a device protection element formed between the thin-film transistor and the flexible substrate, the device protection element surrounding the thin-film transistor, and a buffer layer covering the flexible substrate on which the thin-film transistor and the device protection element are formed.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIGS. 1 to 8 are cross sectional views illustrating a method for manufacturing a semiconductor device according to embodiments of the present invention; and

FIGS. 9 to 11 are cross sectional views illustrating semiconductor devices according to the embodiments of the present invention.

### DETAILED DESCRIPTION OF PREFERRED EMBODIMENTS

Hereinafter, embodiments of the present invention will be described with reference to the accompanying drawings so that the configuration and effects of the present invention are sufficiently understood. However, the present invention is not limited to the embodiments described below, but may be implemented in various forms and may allow various modifications. Rather, the embodiments are provided so that the disclosure of the present invention is thorough and complete and fully conveys the scope of the present invention to those skilled in the art. In the accompanying drawings, the dimensions of elements are magnified for convenience, and the scale ratios among the elements may be exaggerated or reduced.

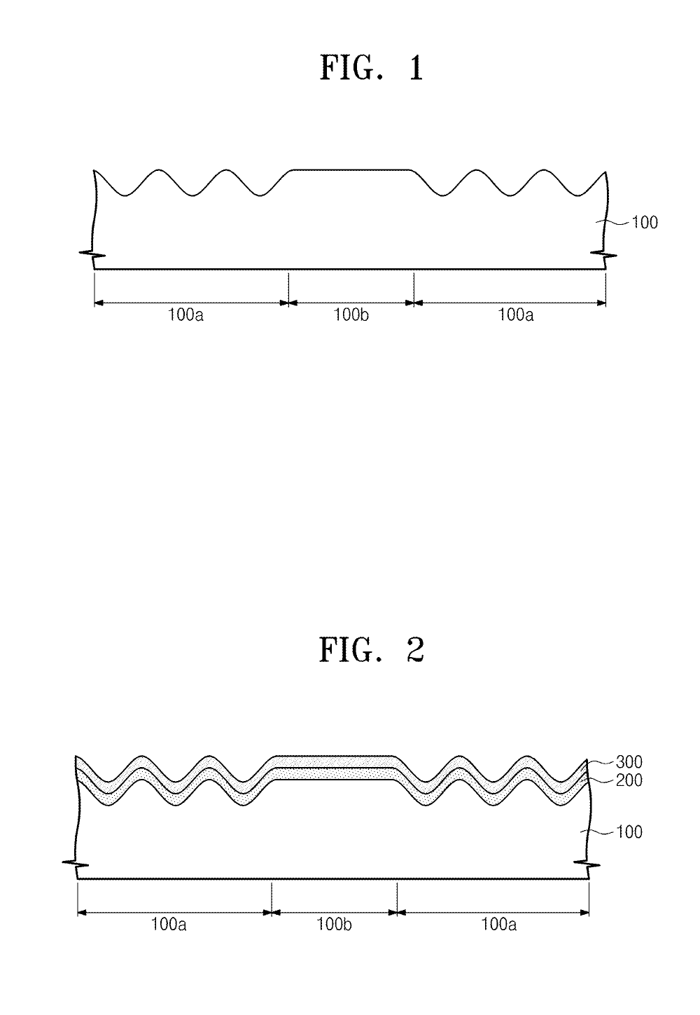

FIGS. 1 to 8 illustrate a method for manufacturing a semiconductor device according to the embodiments of the present invention. The method for manufacturing a semiconductor device according to the embodiments of the present invention may comprise: providing a sacrificial substrate 100 including a wiring region 100a and a device region 100b; sequentially forming a sacrificial layer 200 and a buffer layer 300 on the sacrificial substrate 100; forming a thin-film transistor 400 on the buffer layer 300 of the device region 100b; forming a device protection element 500 surrounding the thin-film transistor 400 within the device region 100b; forming a flexible substrate 600 on the buffer layer 300 on which the device protection element 500 is formed; and exposing a surface of the buffer layer 300 by separating the sacrificial substrate 100 by removing the sacrificial layer 200.

Referring to FIG. 1, the sacrificial substrate 100 may include the wiring region 100a and the device region 100b. The sacrificial substrate 100 may be a silicon substrate or a glass substrate. The sacrificial substrate 100 may have a flat surface in the device region 100b and may have a corrugated surface in the wiring region 100a. For example, forming the corrugated surface in the wiring region 100a of the sacrificial substrate 100 may include: applying a photoresist layer over the sacrificial substrate 100; performing a lithography process to the photoresist layer to form a photoresist pattern exposing parts of the sacrificial substrate 100; etching the sacrificial substrate 100 using the photoresist pattern as an etching mask to form grooves in the sacrificial substrate 100 of the wiring region 100a; and rounding edges of the grooves. For example, the grooves may have the shape of unidirectional waves. For another example, the grooves may have the shape of waves that travel in one direction and another direction perpendicular to the one direction. Depths of the grooves may be about 5 μm to about 10 μm, and widths of the grooves may be about 5 μm to about 10 μm.

Referring to FIG. 2, the sacrificial layer 200 and the buffer layer 300 may be sequentially formed on the sacrificial substrate 100. A material of the sacrificial layer 200 may be determined according to a method of removing the sacrificial layer 200 at a following process. For example, the sacrificial layer 200 may be formed of amorphous silicon (a-Si), silicon oxide, silicon nitride orsilicon oxynitride. For example, the buffer layer 300 may be formed of silicon dioxide (SiO₂). The sacrificial layer 200 and the buffer layer 300 may be formed through chemical vapor deposition (CVD), plasma enhanced chemical vapor deposition (PECVD) or low pressure chemical vapor deposition (LPCVD).

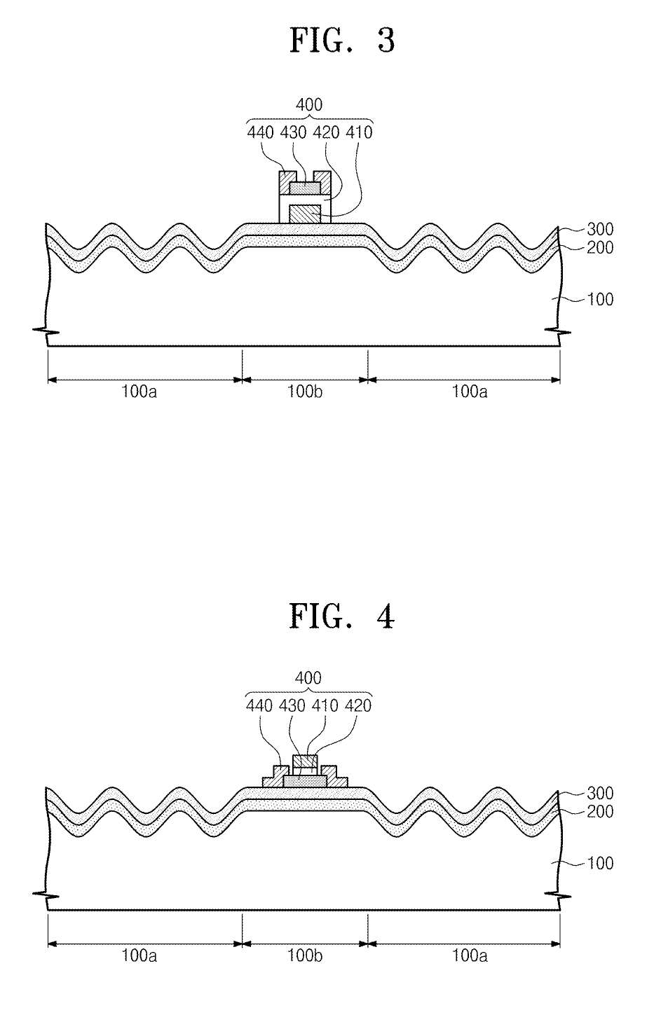

Furthermore, according to an embodiment, the buffer layer 300 may include conductive lines(not shown) electrically connected to the thin-film transistor (reference numeral 400 of FIG. 3). The conductive lines may include a gate line, a source line and a drain line, and may be formed on the buffer layer 300 of the wiring region 100a. Since the conductive lines are formed on the buffer layer 300 having the corrugated surface, the flexibility of the conductive lines may be improved under flexibility conditions.

Referring to FIGS. 3 and 4, the thin-film transistor 400 may be formed on the buffer layer 300 of the device region 100a. The thin-film transistor 400 may include a gate electrode 410, a gate dielectric 420, an active layer 430 and source/drain electrodes 440. For example, the gate electrode 410 and the source/drain electrodes 440 may include any one of an indium tin oxide (ITO), an indium zinc oxide (IZO), a zinc oxide (ZnO), a zinc tin oxide (ZTO), titanium (Ti), aluminum (Al), molybdenum (Mo), platinum (Pt), gold (Au), a titanium-aluminum alloy (Ti/Al/Ti), a molybdenum-aluminum alloy (Mo/Al/Mo) and a carbon nanotube (CNT). For example, the gate dielectric 420 may include aluminum oxide (Al₂O₃), silicon nitride (SiNₓ), silicon oxide (SiOₓ) or a composite layer thereof, or a composite layer of organic layer/inorganic layer. For example, the active layer 430 may include one of zinc oxide, zinc tin oxide, indium zinc oxide, gallium zinc oxide and indium gallium zinc oxide.

Referring to FIG. 3, the thin-film transistor 400 may have a bottom gate structure. The gate electrode 410 may be formed on the buffer layer 300 of the device region 100b. The gate dielectric 420 may cover the gate electrode 410. The active layer 430 may be formed on the gate dielectric 420. The source/drain electrodes 440 may be formed on the active layer 430 while being spaced apart from each other.

Referring to FIG. 4, the thin-film transistor 400 may have a top gate structure. The active layer 430 may be formed on the buffer layer 300 of the device region 100b. The gate dielectric 420 may be formed on the active layer 430. The gate electrode 410 may be formed on the gate dielectric 420. The source/drain electrodes 440 may be formed to be spaced apart from each other at both sides of the gate electrode 410 and may contact with the active layer 430.

The thin-film transistor structures illustrated in FIGS. 3 and 4 are merely examples, and the present invention is not limited thereto. Hereinafter, for conciseness, the present invention will be described on the basis of the thin-film transistor structure illustrated in FIG. 3.

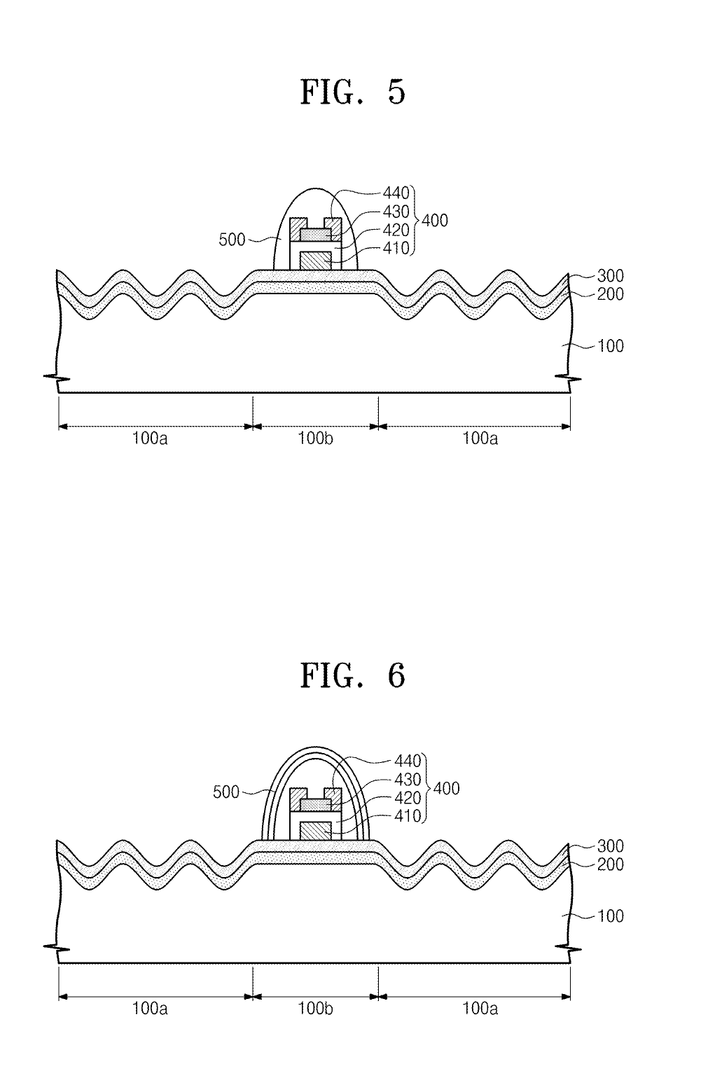

Referring to FIG. 5, the device protection element 500 that surrounds the thin-film transistor 400 within the device region 100b may be formed. The device protection element 500 may be locally formed on the buffer layer 300 on which the thin-film transistor 400 is formed. The device protection element 500 may surround the thin-film transistor 400 on the buffer layer 300 of the device region 100b, and may expose the buffer layer of the wiring region 100a. For example, the device protection element 500 may be formed in the shape of an island.

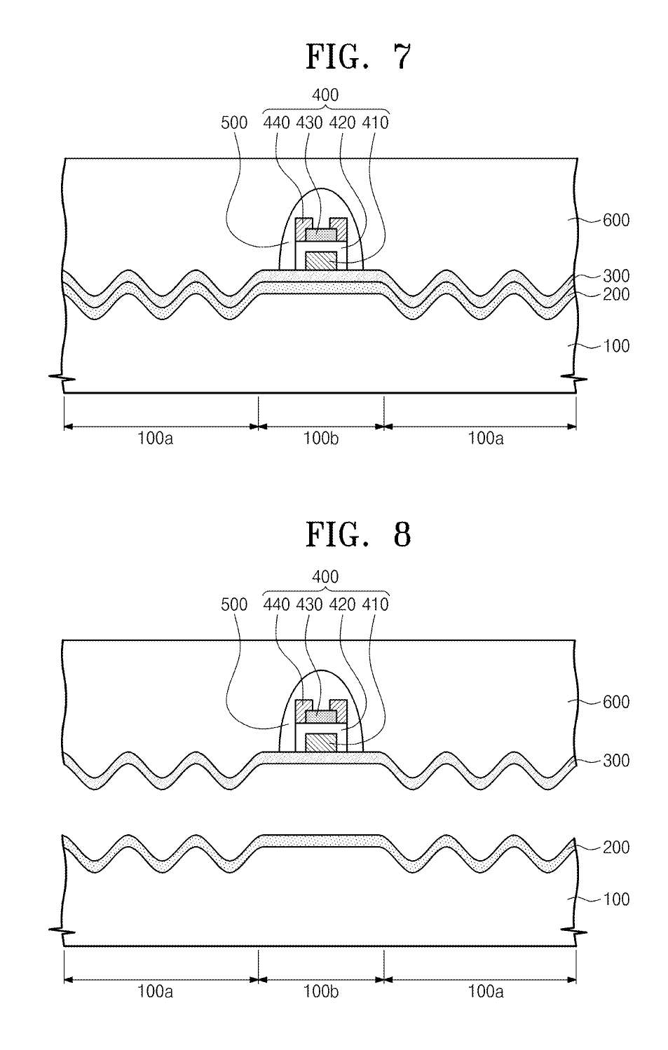

For example, the device protection element 500 may be formed through an inkjet printing process. In this case, as illustrated in the drawings, the device protection element 500 may have a rounded surface. For another example, the device protection element 500 may be formed by forming an organic or inorganic layer on the buffer layer 300 to cover the thin-film transistor 400 and then patterning the organic or inorganic layer. The device protection element 500 may be formed of a material having a Young's modulus greater than that of a material constituting the flexible substrate (reference numeral 600 of FIG. 7). That is, the device protection element 500 may be formed of a material having a strain rate lower than that of the material constituting the flexible substrate. Accordingly, the device protection element 500 may reduce deformation of the thin-film transistor under flexibility conditions. For example, the device protection element 500 may be formed of organic materials such as polyimide, acrylic resin or hard polydimethylsiloxane (h-PDMS) or inorganic materials such as aluminum oxide (Al₂O₃), silicon dioxide (SiO₂) or silicon nitride (SiNₓ). The buffer layer 300 of the device region 100a on which the thin-film transistor 400 is formed is flat and is not deformed under flexibility conditions. Therefore, the inorganic materials may also be included in the materials constituting device protection element 500.

Referring to FIG. 6, the device protection element 500 may have a composite structure in which a plurality of organic layers and inorganic layers exist. As the device protection element 500 has the organic/inorganic composite structure, the device protection element 500 may also serve to passivate the thin-film transistor 400. The composite structure may be formed by repeatedly forming a single layer through an inkjet printing process or a photolithography process.

Referring to FIG. 7, the flexible substrate 600 may be formed on the buffer layer 300 on which the device protection element 500 is formed. The flexible substrate 600 may be formed by casting a flexible material on the buffer layer 300 to cover the device protection element 500. For example, the flexible substrate 600 may be formed of polydimethylsiloxane (PDMS).

Referring to FIG. 8, the sacrificial substrate 100 may be separated by removing the sacrificial layer 200. The sacrificial layer 200 may be removed through a laser lift-off process or a wet etching lift-off process. For example, in the case that the sacrificial substrate 100 is a glass substrate and the sacrificial layer 200 is formed of amorphous silicon (a-Si), the sacrificial layer 200 may be removed through the laser lift-off process. In the laser lift-off process, the sacrificial layer 200 is selectively heated by irradiating laser in a direction from the sacrificial substrate 100 to the sacrificial layer 200 to dissolve the sacrificial layer 200, and thereby the sacrificial substrate 100 is separated. For another example, in the case that the sacrificial layer 200 is formed of silicon oxide, the sacrificial layer 200 may be removed through the wet etching lift-off process.

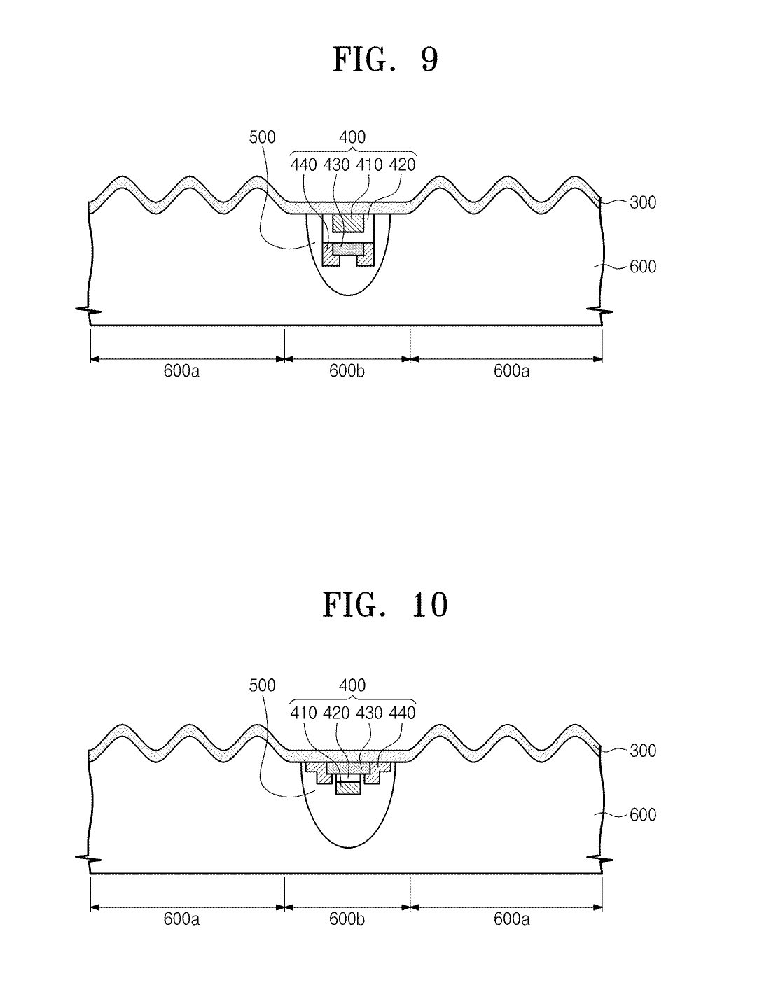

FIGS. 9 to 11 illustrate semiconductor devices according to the embodiments of the present invention. Hereinafter, the structures of the semiconductor devices according to the embodiments of the present invention will be described. Descriptions that duplicate with the above descriptions with respect to methods for forming the elements of the semiconductor devices and materials thereof will be omitted.

Referring to FIGS. 9 and 10, the semiconductor devices according to the embodiments of the present invention may include the flexible substrate 600, the device protection element 500, the thin-film transistor 400, and the buffer layer 300. The thin-film transistor 400 may include the gate electrode 410, the gate dielectric 420, the active layer 430, and the source/drain electrodes 440.

The flexible substrate 600 may include a wiring region 600a and a device region 600b. The flexible substrate 600 may have a corrugated surface in the wiring region 600a and may have a flat surface in the device region 600b. The thin-film transistor 400 may be embedded within the flexible substrate 600 of the device region 600b. The device protection element 500 may be disposed between the thin-film transistor 400 and the flexible substrate 600 while surrounding the thin-film transistor 400 in the device region 600b. The buffer layer 300 may cover the device protection element 500 and the flexible substrate 600.

The thin-film transistor 400 may include the gate electrode 410, the gate dielectric 420, the active layer 430 and the source/drain electrodes 440. Referring to FIG. 9, for example, the gate electrode 410 may be disposed to contact with a lower surface of the buffer layer 300 of the device region 600b. The active layer 430 may be disposed under the gate electrode 410. The gate dielectric 420 may be disposed between the gate electrode 410 and the active layer 430. The source/drain electrodes 440 may be spaced apart from each other under the active layer 430, and may contact with the active layer 430. Referring to FIG. 10, for another example, the active layer 430 may be disposed to contact with the lower surface of the buffer layer 300 of the device region 600b. The gate electrode 410 may be disposed under the active layer 430. The gate dielectric 420 may be disposed between the active layer 430 and the gate electrode 410. The source/drain electrodes 440 may be spaced apart from each other at both sides of the gate electrode 410 and may contact with the active layer 430.

In one embodiment, the device protection element 500 may be locally formed on the buffer layer 300 on which the thin-film transistor 400 is formed. For example, the device protection element 500 may be formed in the shape of an island. Furthermore, as illustrated in the drawings, the device protection element 500 may have a rounded surface. The device protection element 500 may include a material having a Young's modulus greater than that of a material constituting the flexible substrate 600. That is, the device protection element 500 may be formed of a material having a strain rate lower than that of the material constituting the flexible substrate. Accordingly, the device protection element 500 may reduce deformation of the thin-film transistor under flexibility conditions.

Furthermore, according to some embodiments, the buffer layer 300 may include conductive lines(not shown) electrically connected to the thin-film transistor 400. The conductive lines may include a gate line, a source line and a drain line, and may be formed on the buffer layer 300 of the wiring region 100a. As the conductive lines are formed on the buffer layer 300 having the corrugated surface, the flexibility of the conductive lines may be improved under flexibility conditions.

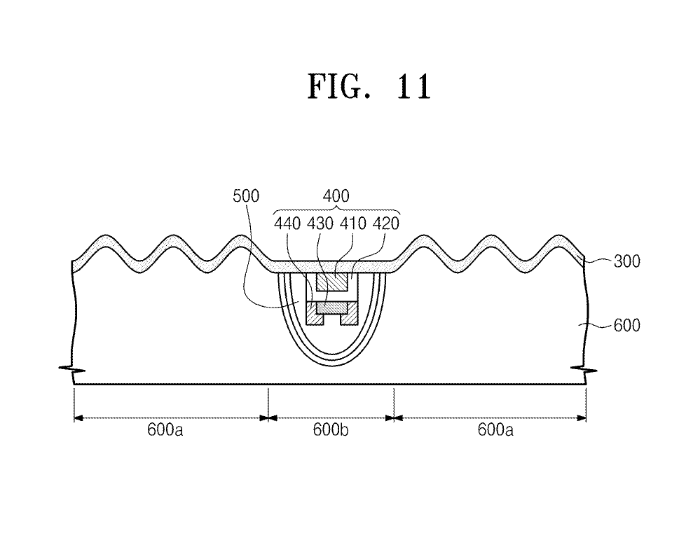

Referring to FIG. 11, the device protection element 500 may have a composite structure in which a plurality of organic layers and inorganic layers exist. As the device protection element 500 has the organic/inorganic composite structure, the device protection element 500 may also serve to passivate the thin-film transistor 400.

According to the embodiments of the present invention, since typical semiconductor process technologies may be directly used, the process compatibility may be improved, and semiconductor devices having high resolution and high performance may be manufactured.

According to the embodiments of the present invention, since the thin-film transistor is surrounded and protected by the device protection element, the deformation of semiconductor devices under flexibility conditions may be prevented, thereby improving the reliability of the semiconductor devices.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A method for manufacturing a semiconductor device, the method comprising:
providing a sacrificial substrate including a wiring region and a device region;
forming sequentially a sacrificial layer and a buffer layer on the sacrificial substrate;
forming a thin-film transistor on the buffer layer of the device region;
forming a device protection element surrounding the thin-film transistor within the device region;
forming a flexible substrate on the buffer layer on which the device protection element is formed; and
exposing a surface of the buffer layer by separating the sacrificial substrate by removing the sacrificial layer.

2. The method of claim 1, wherein the sacrificial substrate has a surface that is more corrugated in the wiring region than in the device region.

3. The method of claim 1, wherein the removing the sacrificial layer is performed using a laser lift-off technique.

4. The method of claim 1, wherein the forming the device protection element is performed using an inkjet printing process.

5. The method of claim 1, wherein the forming the device protection element is performed using a photolithography process.

6. The method of claim 1, wherein a material constituting the device protection element has a Young's modulus greater than that of a material constituting the flexible substrate.

7. A semiconductor device comprising:
a flexible substrate including a device region and a wiring region;
a thin-film transistor embedded within the flexible substrate of the device region;
a device protection element formed between the thin-film transistor and the flexible substrate, the device protection element surrounding the thin-film transistor; and
a buffer layer covering the flexible substrate on which the thin-film transistor and the device protection element are formed.

8. The semiconductor device of claim 7, wherein the thin-film transistor comprises:
a gate electrode;
an active layer formed under the gate electrode;
a gate dielectric between the gate electrode and the active layer; and
source and drain electrodes spaced apart from each other under the active layer, the source and drain electrodes contacting with the active layer.

9. The semiconductor device of claim 7, wherein the thin-film transistor comprises:
an active layer;
a gate electrode formed under the active layer;
a gate dielectric formed between the active layer and the gate electrode; and
source and drain electrodes spaced apart from each other at both sides of the gate electrode, the source and drain electrodes contacting with the active layer.

10. The semiconductor device of claim 7, wherein the flexible substrate has a surface that is more corrugated in the wiring region than in the device region.

11. The semiconductor device of claim 7, wherein a material constituting the device protection element has a Young's modulus greater than that of a material constituting the flexible substrate.

12. The semiconductor device of claim 7, wherein the device protection element is formed of at least one selected from polyimide, acrylic resin and hard polydimethylsiloxane (h-PDMS).

13. The semiconductor device of claim 7, wherein the device protection element is formed of at least one selected from aluminum oxide (Al₂O₃), silicon dioxide (SiO₂) and silicon nitride (SiNₓ).

14. The semiconductor device of claim 7, wherein the device protection element includes a plurality of layers.
